(19) United States
(12) Patent Application Publication
(10) Pub. No.: US 2012/0305887 A1
(43) Pub. Date: Dec. 6, 2012

(54) WHITE LIGHT EMITTING DIODE HAVING PHOTOLUMINESCENT LAYER

(76) Inventors: Qing-Hua Wang, Dong Guan (CN); Lung-Chien Chen, New Taipei (TW); Tsung-Yu Hsieh, Kaohsiung (TW); Ching-Ho Tien, Changhua (TW)

(21) Appl. No.: 13/118,593

(22) Filed: May 31, 2011

(51) Int. Cl. H01L 33/04

(52) U.S. Cl. 257/13; 257/E33.008

(57) ABSTRACT

A white LED having a photoluminescent layer is provided, which includes a sapphire substrate, a gallium nitride buffer layer, an n-type gallium nitride layer, an aluminium gallium nitride multiquantum well, a p-type gallium nitride layer, a transparent conductive layer, a terbium-doped indium oxide layer as photoluminescent layer, a negative electrode, and a positive electrode, wherein the gallium nitride buffer layer, the n-type gallium nitride layer, the aluminium gallium nitride multiquantum well, the p-type gallium nitride layer, the transparent conductive layer, the terbium-doped indium oxide layer are sequentially formed on the sapphire substrate, and the negative electrode is formed on the exposed portion of the n-type gallium nitride layer and is electrically connected to the negative terminal V− of the power source, and the positive electrode is formed on the terbium-doped indium oxide layer and is electrically connected to the positive terminal V+ of the power source.

### BACKGROUND OF THE INVENTION

1. Field of the Invention

The present invention generally relates to a light emitting diode, and in particular to a GaN-based white light emitting diode (LED) having a terbium-doped indium oxide (In₂O₃:Tb) transparent conductivity layer with photoluminescence properties.

2. The Prior Arts

LEDs are rapidly evolving for use in the special and general illumination applications. In an LED, the electrons and holes can recombine in the vicinity of a p-n junction to emit light when a forward bias current flows. Because the wavelength of light emitted, and thus its color depends on the energy gaps of the materials, the desired visible light can be emitted by variation in the energy gap between different semiconductor materials forming the p-n junction.

The UV light from the LED light source can be converted into the visible light through the phosphor added in a transparent resin. However, the transparent resin has the disadvantage of aging which will deteriorate the optical quality of the light emitted by an LED. Therefore, there is a need to provide a white light emitting diode having a photoluminescent layer for improving the optical quality of the light emitted by an LED when it is used for a long time.

### SUMMARY OF THE INVENTION

Accordingly, the objective of the present invention is to provide a white LED having a photoluminescent layer in order to overcome the problems set forth above.

To achieve the foregoing objective, the present invention provides a white LED having a photoluminescent layer, which includes a sapphire substrate, a gallium nitride buffer layer, an n-type gallium nitride layer, an aluminium gallium nitride multiquantum well, a p-type gallium nitride layer, a transparent conductive layer, a terbium-doped indium oxide (In₂O₃:Tb) layer as photoluminescent layer, a negative electrode, and a positive electrode, wherein the gallium nitride buffer layer, the n-type gallium nitride layer, the aluminium gallium nitride multiquantum well, the p-type gallium nitride layer, the transparent conductive layer, the terbium-doped indium oxide layer are sequentially formed on the sapphire substrate, and the negative electrode is formed on the exposed portion of the n-type gallium nitride layer and is electrically connected to the negative terminal V− of the power source, and the positive electrode is formed on the terbium-doped indium oxide layer and passes through the terbium-doped indium oxide layer for allowing it to be contacted with the transparent conductive layer, and the positive electrode is electrically connected to the positive terminal V+ of the power source.

Electric current will flow from the positive electrode, through the transparent conductive layer, the p-type gallium nitride layer, the aluminium gallium nitride multiquantum well, and the n-type gallium nitride layer, to the negative electrode. Electrical current is converted directly into light via radiative recombination of electrons and holes in the aluminium gallium nitride multiquantum well. The light emitted will pass through the p-type gallium nitride layer, the transparent conductive layer, and the photoluminescence properties of the terbium-doped indium oxide layer in which the light will be converted into the white light that we see, and then the white light is subsequently emitted outward from the LED.

Therefore, UV light will be converted into the white light when the white LED having a photoluminescent layer of the present invention is used without using a phosphor in a transparent resin. Accordingly, the problems of aging of the transparent resin used in an LED will be overcome.

The foregoing and other objectives, features, aspects and advantages of the present invention will become better understood from a careful reading of a detailed description provided herein below with appropriate reference to the accompanying drawings.

### BRIEF DESCRIPTION OF THE DRAWINGS

FIG. 1 shows a schematic view of the structure of the white LED having a photoluminescent layer according to the present invention;

FIG. 2 shows the temperature-dependent photoluminescence spectra of the white LED having the photoluminescent layer according to one embodiment of the present invention;

FIG. 3 shows the temperature-dependent photoluminescence spectra of the white LED having the photoluminescent layer according to another embodiment of the present invention;

FIG. 4 shows the electroluminescence spectra of the white LED without the photoluminescent layer according to one embodiment of the present invention;

FIG. 5 shows the electroluminescence spectra of the white LED with the photoluminescent layer according to one embodiment of the present invention;

FIG. 6 shows the electroluminescence spectra of the white LED without the photoluminescent layer according to another embodiment of the present invention; and

FIG. 7 shows the electroluminescence spectra of the white LED with the photoluminescent layer according to another embodiment of the present invention.

### DETAILED DESCRIPTION OF THE PREFERRED EMBODIMENT

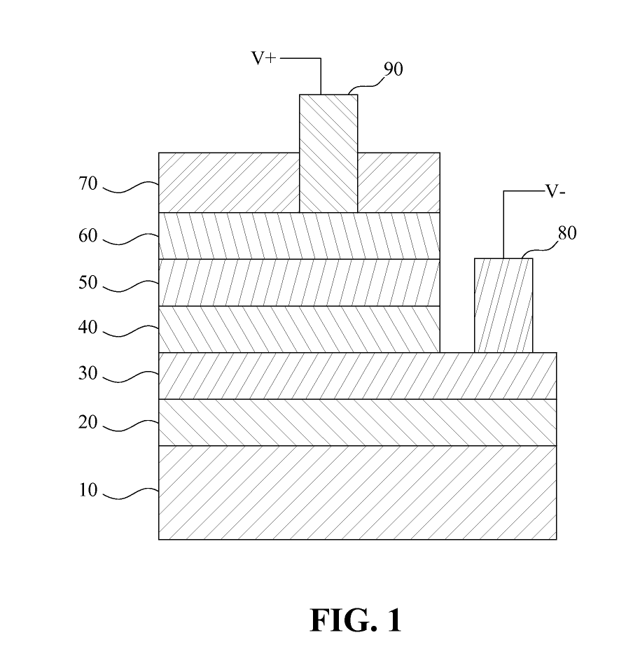

FIG. 1 shows a schematic view of the structure of a white LED having a photoluminescent layer according to the present invention. Referring to FIG. 1, the white LED having a photoluminescent layer of the present invention comprises a sapphire substrate 10, a gallium nitride (GaN) buffer layer 20, an n-type gallium nitride (n-GaN) layer 30, an aluminium gallium nitride (AlGaN) multiquantum well (MQW) 40, a p-type gallium nitride (p-GaN) layer 50, a transparent conductive layer 60, a terbium-doped indium oxide (In₂O₃:Tb) layer 70 as photoluminescent layer, a negative electrode 80, and a positive electrode 90.

The GaN buffer layer 20, the n-GaN layer 30, the AlGaN MQW 40, the p-GaN layer 50, the transparent conductive layer 60, the In₂O₃:Tb layer 70 are sequentially formed on the sapphire substrate 10. A portion of the n-GaN layer 30 is exposed, and a negative electrode 80 is formed on the exposed portion of the n-GaN layer 30. The negative electrode 80 is electrically connected to the negative terminal V− of the power source. The positive electrode 90 is formed on the In₂O₃:Tb layer 70 and is electrically connected to the positive terminal V+ of the power source. The In₂O₃:Tb layer 70 has a throughhole which reaches to the transparent conductive layer 60, and the positive electrode 90 passes through this throughhole for allowing it to be contacted with the transparent conductive layer 60.

The AlGaN MQW 40 is formed as a result of a repetitive and alternate stacking of the AlGaN quantum well layers having different energy gaps. The radiative recombination of electrons and holes is found to be localized mainly in the MQW 40. The luminous intensity of the MQW 40 is increased with the AlGaN quantum well layers having relative low energy gaps.

Electric current will then flow from the positive electrode 90, through the transparent conductive layer 60, the p-GaN layer 50, the AlGaN MQW 40, and n-GaN layer 30, to the negative electrode 80. Electrical current is converted directly into light via radiative recombination of electrons and holes in the AlGaN MQW 40. The light will sequentially pass through the p-GaN layer 50, the transparent conductive layer 60, and the In₂O₃:Tb layer 70 in which the light produced will be converted into the white light, and then the white light is subsequently emitted outward to provide useful illumination.

The In₂O₃:Tb (TIO) layer 70 is transparent, and the weight ratio between In₂O₃ and Tb is from 95:5 to 5:95. The In₂O₃:Tb layer 70 is formed on the transparent conductive layer 60 by, for example, RF reactive magnetron sputtering method.

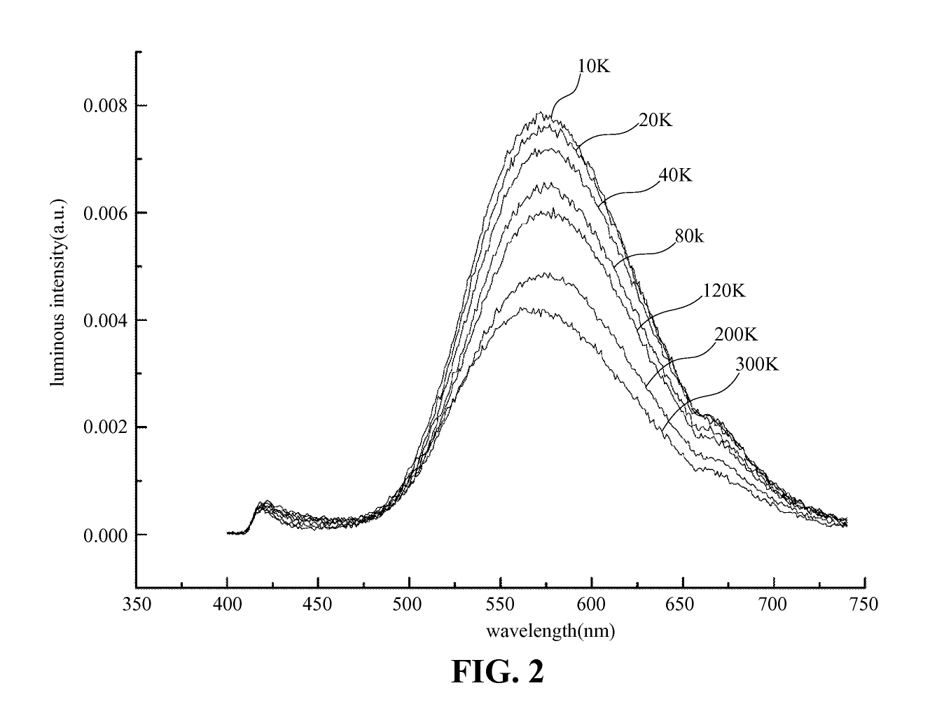

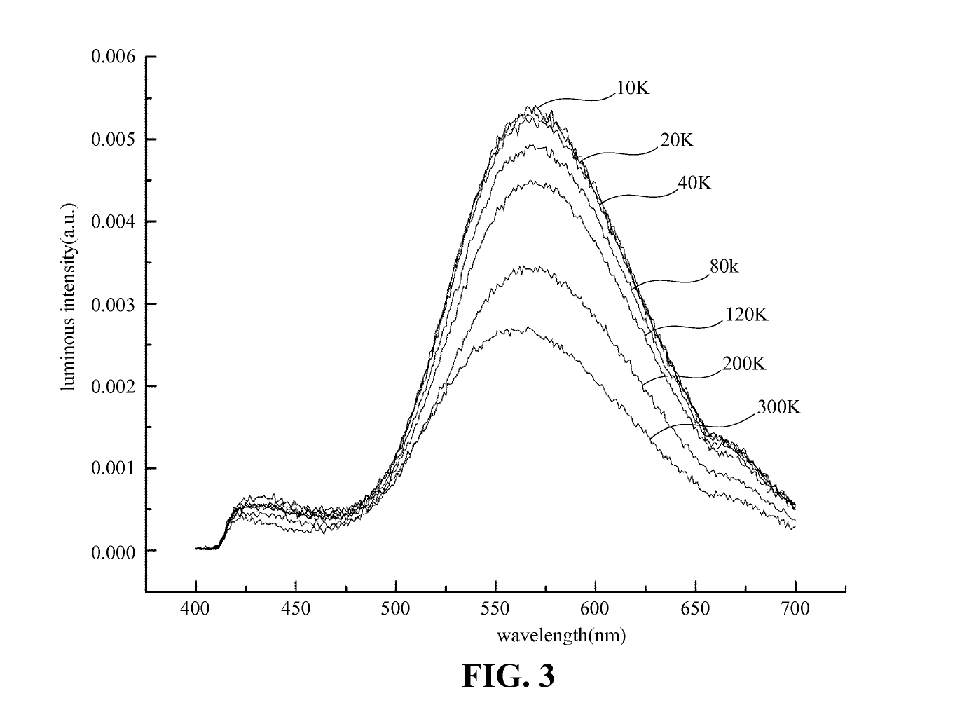

FIG. 2 shows the temperature-dependent photoluminescence spectra of the white LED having the photoluminescent layer according to one embodiment of the present invention in which the weight ratio between In₂O₃ and Tb is 90:10, and the temperature is varied from 10 K to 300 K. FIG. 3 shows the temperature-dependent photoluminescence spectra of the white LED having the photoluminescent layer according to another embodiment of the present invention in which the weight ratio between In₂O₃ and Tb is 80:20, and the temperature is varied from 10 K to 300 K. FIG. 2 shows a luminescence band with a broad peak around 575 nm, and FIG. 3 shows a luminescence band with a broad peak around 565 nm.

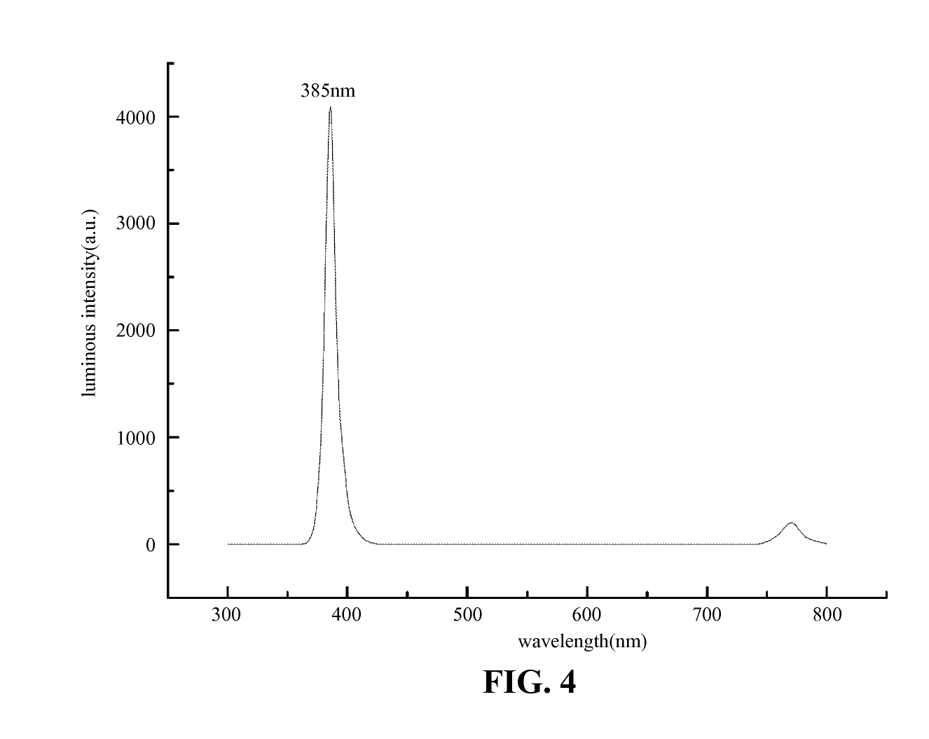

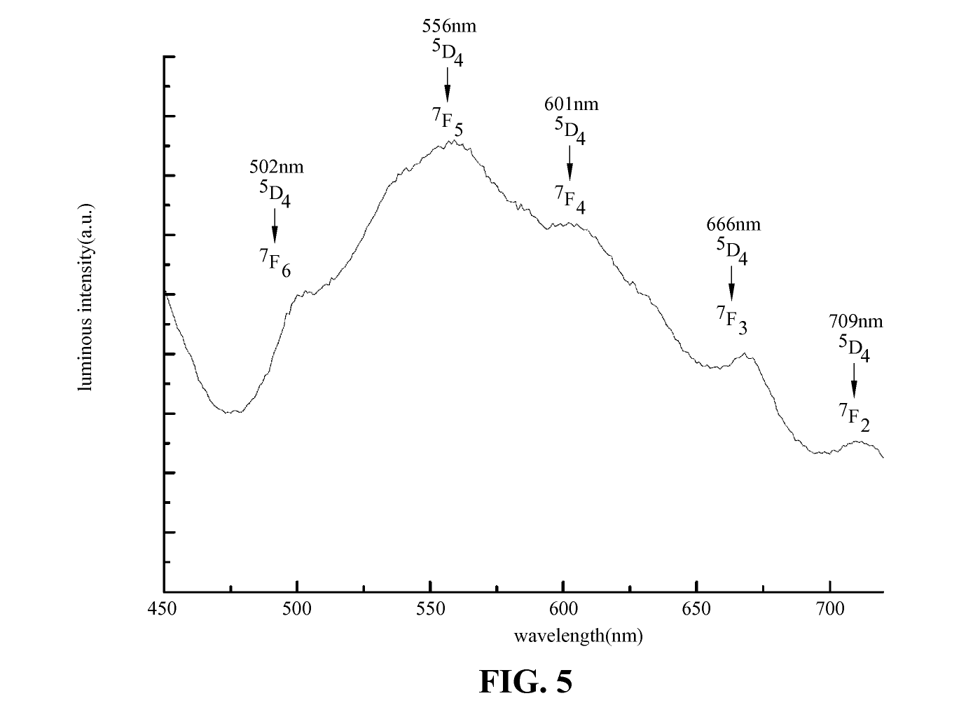

FIGS. 4 and 5 respectively shows an electroluminescence spectra for the white LED without and with the photoluminescent layer according to one embodiment of the present invention in which the weight ratio between In₂O₃ and Tb is 90:10, and the supply of electric current is 100 mA. Referring to FIG. 4, the 385 nm of UV light is emitted by the white LED without the photoluminescent layer according to the present invention. Referring to FIG. 5, the molecular orbital transitions from d orbital to f orbital at from 450 nm to 700 nm are shown according to one embodiment of the present invention.

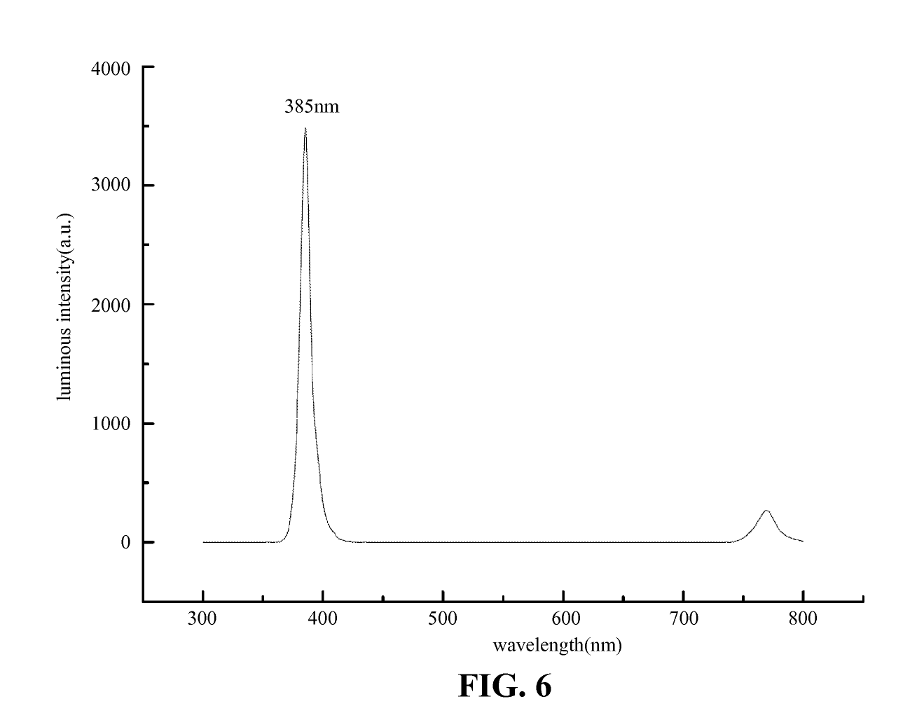

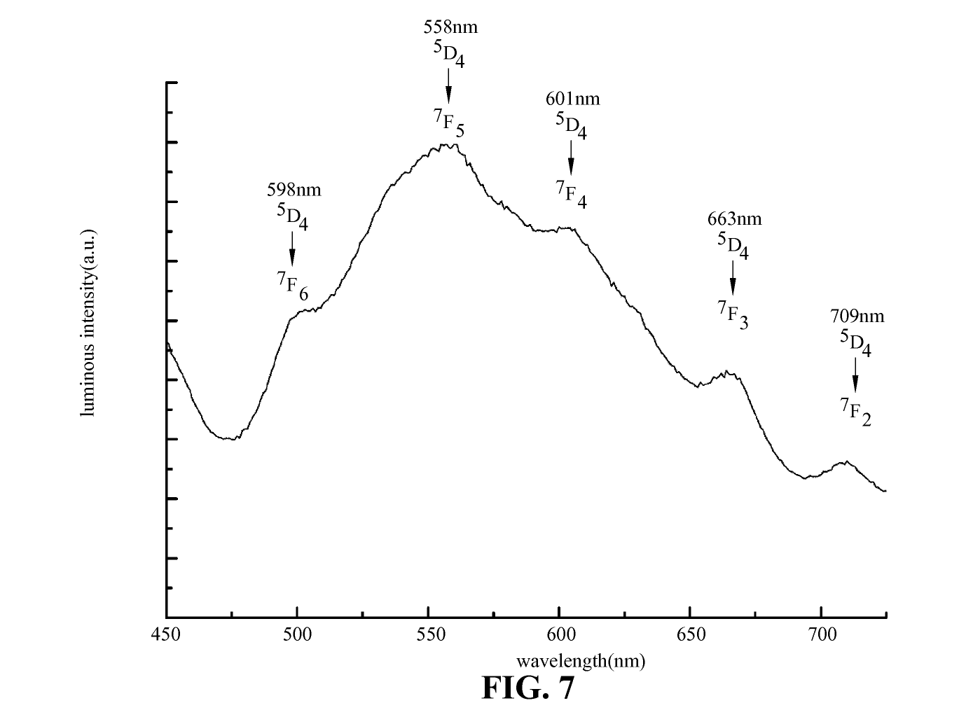

FIGS. 6 and 7 respectively shows an electroluminescence spectra for the white LED without and with the photoluminescent layer according to another embodiment of the present invention in which the weight ratio between In₂O₃ and Tb is 80:20, and the supply of electric current is 100 mA. Referring to FIG. 6, the 385 nm of UV light is emitted by the white LED without the photoluminescent layer according to another embodiment of the present invention. Referring to FIG. 7, the molecular orbital transitions from d orbital to f orbital at from 450 nm to 700 nm are shown according to another embodiment of the present invention.

From FIGS. 2 to 7, it is apparent that the white light can be emitted by the white LED having a photoluminescent layer of the present invention. Therefore, the white LED having a photoluminescent layer of the present invention can be used as a backlight source for liquid crystal displays, or used in general illumination applications.

It will be apparent to those skilled in the art that various modifications and variations can be made in the present invention without departing from the spirit or scope of the present invention. Thus, it is intended that the present invention cover the modifications and the variations of this invention provided they come within the scope of the appended claims and their equivalents.

What is claimed is:

1. A white light emitting diode having a photoluminescent layer, comprising:
a sapphire substrate;
a gallium nitride buffer layer formed on the sapphire substrate;
an n-type gallium nitride layer formed on the gallium nitride buffer layer;
an aluminium gallium nitride multiquantum well formed on the n-type gallium nitride layer, a portion of the n-type gallium nitride layer being exposed;
a p-type gallium nitride layer formed on the aluminium gallium nitride multiquantum well;
a transparent conductive layer formed on the p-type gallium nitride layer;
a terbium-doped indium oxide (In₂O₃:Tb) layer as the photoluminescent layer formed on the transparent conductive layer, the terbium-doped indium oxide layer having a throughhole which reaches to the transparent conductive layer;
a positive electrode formed on the terbium-doped indium oxide layer, the positive electrode passing through the throughhole and being contacted with the transparent conductive layer, the positive electrode being electrically connected to a positive terminal of a power source; and
a negative electrode formed on the exposed portion of the n-type gallium nitride layer, the negative electrode being electrically connected to a negative terminal of the power source.

2. The white light emitting diode as claimed in claim 1, wherein a weight ratio between In₂O₃ and Tb in the terbium-doped indium oxide (In₂O₃:Tb) layer is from 95:5 to 5:95.

3. The white light emitting diode as claimed in claim 1, wherein the terbium-doped indium oxide layer is formed on the transparent conductive layer by a RF reactive magnetron sputtering method.

4. The white light emitting diode as claimed in claim 1, wherein the aluminium gallium nitride multiquantum well is formed as a result of a repetitive and alternate stacking of aluminium gallium nitride quantum well layers having different energy gaps.
